(19) United States
(12) Patent Application Publication
(10) Pub. No.: US 2016/0037690 A1
(43) Pub. Date: Feb. 4, 2016

(54) ELECTROMAGNETIC SHIELD BODY AND BOX

(71) Applicant: TOYOTA JIDOSHA KABUSHIKI KAISHA, Toyota-shi (JP)

(72) Inventors: Fumio NOMIZO, Toyota-shi (JP); Hideo SATAKE, Nagoya-shi (JP); Tetsuyoshi FUKAYA, Tokai-shi (JP); Hirofumi INOSHITA, Nagoya-shi (JP)

(73) Assignee: TOYOTA JIDOSHA KABUSHIKI KAISHA, Toyota-shi (JP)

(21) Appl. No.: 14/799,906

(22) Filed: Jul. 15, 2015

(30) Foreign Application Priority Data
Jul. 29, 2014 (JP) 2014-154291

(51) Int. Cl. H05K 9/00

(52) U.S. Cl. CPC H05K 9/0049; H05K 9/005

(57) ABSTRACT

An electromagnetic shield body includes a metal plate and insulating resin combined with each other by insert molding. The metal plate is provided with a projection portion projecting into the insulating resin from the metal plate. The projection portion has a supporting side that dams up and holds the insulating resin introduced into a space defined by the projection portion.

### INCORPORATION BY REFERENCE

The disclosure of Japanese Patent Application No. 2014-154291 filed on Jul. 29, 2014 including the specification, drawings and abstract is incorporated herein by reference in its entirety.

### BACKGROUND OF THE INVENTION

1. Field of the Invention

The invention relates to an electromagnetic shield body and a box.

2. Description of Related Art

Japanese Patent No. 4382396 discloses an electromagnetic wave shield housing having a structure in which an insert material, which is a metal plate made of aluminum or copper, is sandwiched between a resin inner wall and a resin outer wall. The insert material has through-holes. A part of the resin constituting the inner wall extends through each through-hole and protrudes from the opposite side of the insert material from the inner wall. The protruding portion of the resin has a larger diameter than that of the through-hole. With this configuration, the inner wall and the insert material are firmly combined with each other.

### SUMMARY OF THE INVENTION

The invention provides a technique for firmly combining a metal plate and insulating resin with each other.

An aspect of the invention is an electromagnetic shield body including a metal plate and insulating resin combined with each other by insert molding. The metal plate is provided with a projection portion projecting into the insulating resin from the metal plate. The projection portion has a supporting side that dams up and holds the insulating resin introduced into a space defined by the projection portion. According to the structure, the metal plate and the insulating resin are firmly combined with each other. The projection portion may be formed by subjecting a part of the metal plate to lancing and may cover a hole left in the metal plate through the lancing. The above structure enables to form the projection portion at a low cost and to maintain shielding effectiveness. The projection portion may have a beam-shape and may be supported at one end by the metal plate. The projection portion may have a beam-shape and may be supported at both ends by the metal plate. The projection portion may be a curved portion. The projection portion may be entirely embedded in the insulating resin. According to the structure, the projection portion is not exposed on the surface of the insulating resin so that insulating quality of the insulating resin is surely maintained. Another aspect of the invention is a box provided with side-walls including the above electromagnetic shield body. The insulating resin of the electromagnetic shield body is disposed on an inner side of the metal plate in the box, and the projection portion extends upward from a lower end of the hole. According to the structure, an electromagnetic wave generated by an electric component placed near the bottom of the electromagnetic shield housing is able to be effectively blocked.

According to the above aspects, the metal plate and the insulating resin are firmly combined with each other.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a perspective view of an electromagnetic shield housing in a first embodiment of the invention;

FIG. 2 is a partially enlarged perspective view of a metal plate in the first embodiment;

FIG. 3 is a horizontal sectional view taken along the line III-III in FIG. 2;

FIG. 4 is a front view of the metal plate as viewed from a direction of an arrow IV in FIG. 2;

FIG. 5 is a partial horizontal sectional view of a side-wall of the electromagnetic shield housing in the first embodiment;

FIG. 6 is a partial horizontal sectional view of a side-wall of an electromagnetic shield housing in a second embodiment of the invention;

FIG. 7 is a partial perspective view of a metal plate in a third embodiment of the invention;

FIG. 8 is a vertical sectional view taken along the line VIII-VIII in FIG. 7; and

FIG. 9 is a partial vertical sectional view of a side-wall of an electromagnetic shield housing in the third embodiment.

### DETAILED DESCRIPTION OF EMBODIMENTS

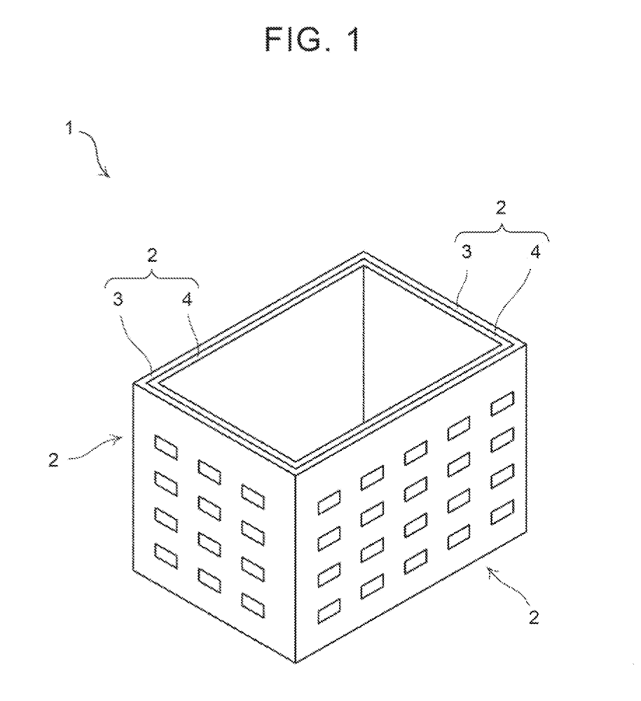

Hereinafter, with reference to FIGS. 1 to 5, a first embodiment of the invention will be described.

FIG. 1 shows an electromagnetic shield housing 1 (an example of a box in the invention). The electromagnetic shield housing 1 is disposed in, for example, an engine compartment of a vehicle. The electromagnetic shield housing 1 is a housing in which electronic equipment, such as an inverter, is housed. The electromagnetic shield housing 1 includes four side-walls 2 (each of which is an example of an electromagnetic shield body in the invention). Each of the side-walls 2 is an insert-molded product composed of a metal plate 3 (a conductive plate) and insulating resin 4. That is, each side-wall 2 has two layers composed of the metal plate 3 and the insulating resin 4. The insulating resin 4 is disposed on the inner side of the metal plate 3, so that the electronic equipment housed in the electromagnetic shield housing 1 does not make direct contact with the metal plate 3.

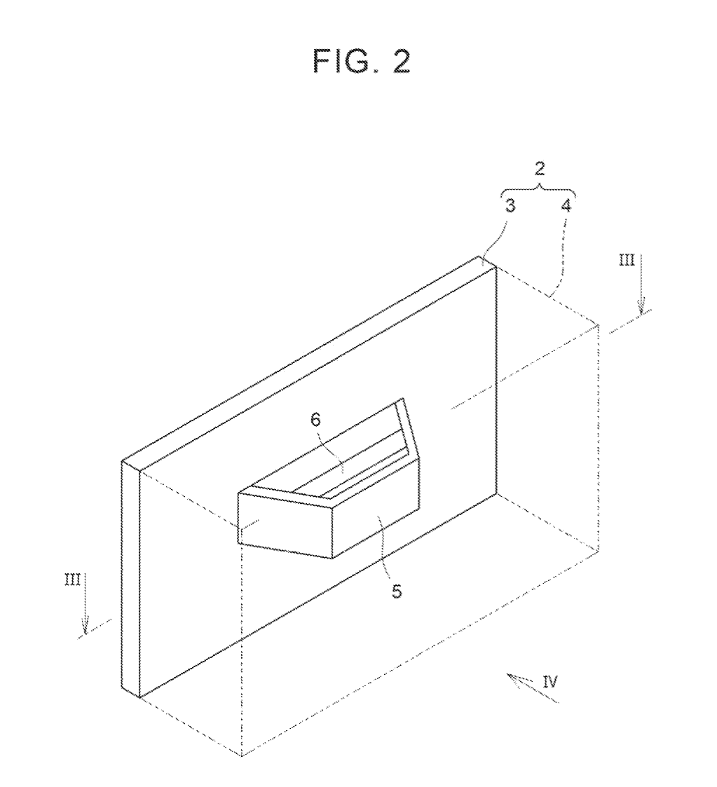

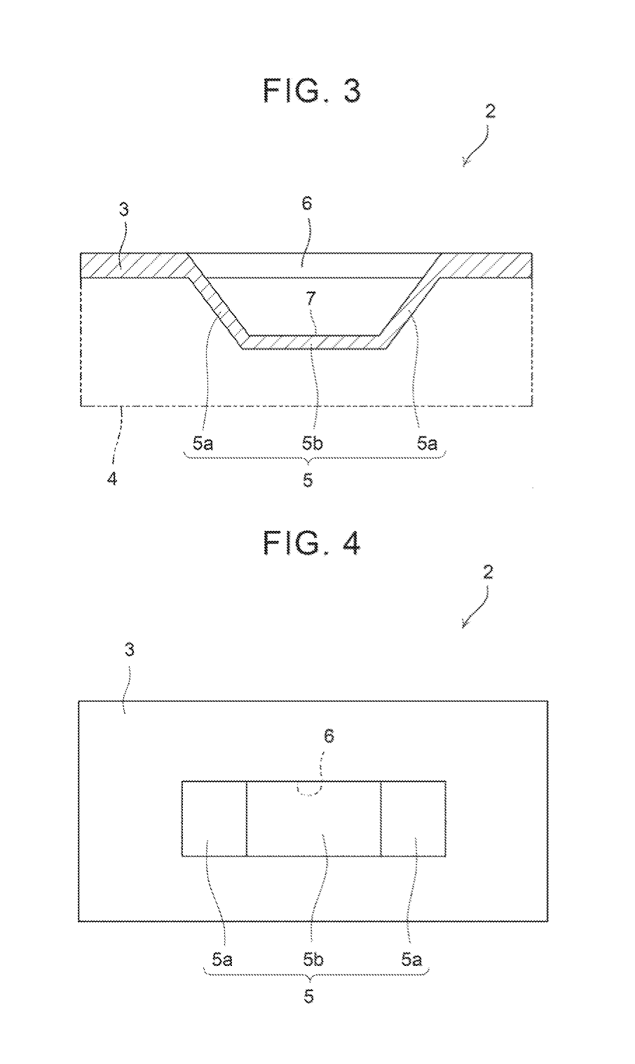

Next, the metal plate 3 will be described in detail with reference to FIGS. 2 to 4. As shown in FIGS. 2 and 3, the metal plate 3 has projection portions 5 projecting from the metal plate 3 into the insulating resin 4. Each of the projection portions 5 is formed by subjecting a part of the metal plate 3 to lancing. Forming the projection portions 5 by lancing leaves holes 6 in the metal plate 3. As shown in FIG. 4, each hole 6 is completely covered with the projection portion 5 in a front view of the metal plate 3 as viewed from a direction of an arrow IV in FIG. 2. Accordingly, shielding effectiveness of the metal plate 3 is maintained.

In the first embodiment, each projection portion 5 has a horizontal beam-shape and is supported at both ends by the metal plate 3. As specifically shown in FIG. 3, the projection portion 5 has a pair of slopes 5a and a supporting portion 5b. The slopes 5a extend obliquely from the metal plate 3. The supporting portion 5b extends parallel to the metal plate 3 and connects distal ends of the slopes 5a to each other. The supporting portion 5b has a supporting side 7 facing the hole 6. The supporting side 7 is oriented toward the metal plate 3 side.

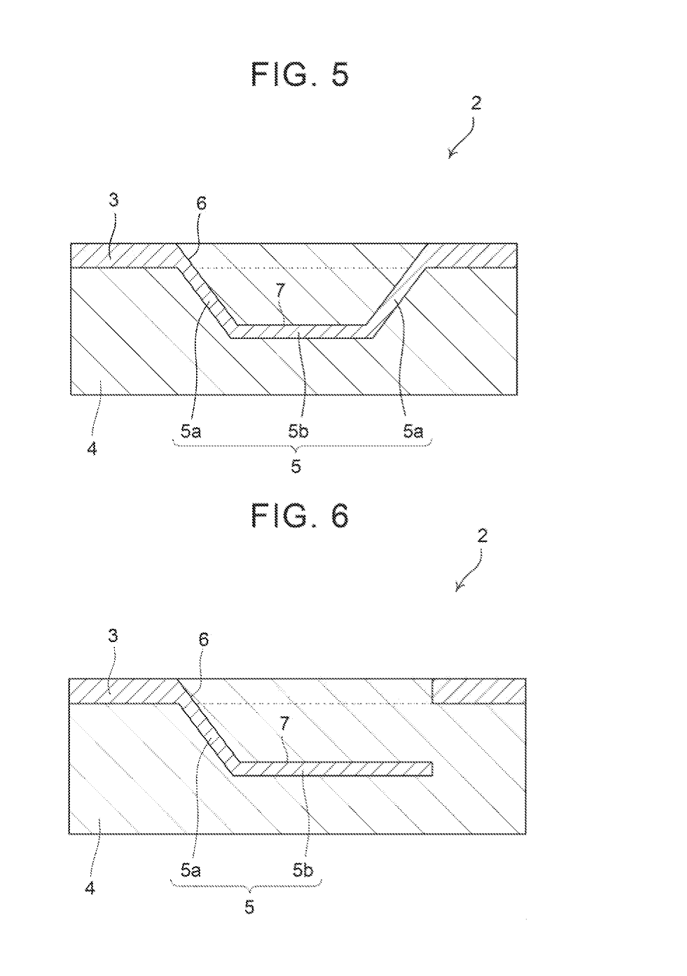

Next, with reference to FIG. 5, the insert molding through which the metal plate 3 and the insulating resin 4 are combined with each other will be described. First, the metal plate 3 is set in a molding die and the molding die is clamped. Then, molten resin is injected into a cavity of the molding die. As shown in FIG. 5, the insulating resin 4 accumulates on the metal plate 3 and some molten resin is introduced into a space defined by the projection portion 5 and communicated with the hole 6. The molten resin introduced into the space defined by the projection portion 5 and communicated with the hole 6 is cured. Therefore, the metal plate 3 and the insulating resin 4 are firmly combined with each other. At the same time, the holes 6 are filled with the molten resin.

As shown in FIG. 5, the projection portions 5 are entirely embedded in the insulating resin 4. That is, the projection portions 5 are not exposed on the surface of the insulating resin 4. Accordingly, insulating quality of the insulating resin 4 is surely maintained.

The features of the first embodiment will be summarized as follows.

The side-wall 2 (an example of the electromagnetic shield body in the invention) is the insert-molded product composed of the metal plate 3 and the insulating resin 4. The metal plate 3 has the projection portions 5 projecting from the metal plate 3 into the insulating resin 4. Each projection portion 5 has the supporting side 7 that dams up and holds the insulating resin 4 introduced into the space defined by the projection portion 5 and communicated with the hole 6. The above structure can firmly combine the metal plate 3 and the insulating resin 4 with each other.

Next, a second embodiment of the invention will be described with reference to FIG. 6. Hereafter, features different from those of the first embodiment will be described and descriptions on the same features as those of the first embodiment will be omitted.

As shown in FIG. 5, each projection portion 5 of the first embodiment has a pair of the slopes 5a and the supporting portion 5b. By contrast, as shown in FIG. 6, each projection portion 5 of the second embodiment has a slope 5a and a supporting portion 5b. That is, in the second embodiment, the projection portion 5 has a horizontal beam-shape and is supported at one end by the metal plate 3.

Each hole 6 of the second embodiment is completely covered with the projection portion 5. Accordingly, shielding effectiveness of the metal plate 3 is maintained.

In the insert molding, some molten resin introduced into the spaces defined by the projection portions 5 and communicated with the holes 6 is cured. Therefore, the metal plate 3 and the insulating resin 4 are firmly combined with each other.

The projection portions 5 are entirely embedded in the insulating resin 4. That is, the projection portions 5 are not exposed on the surface of the insulating resin 4. Accordingly, insulating quality of the insulating resin 4 is surely maintained.

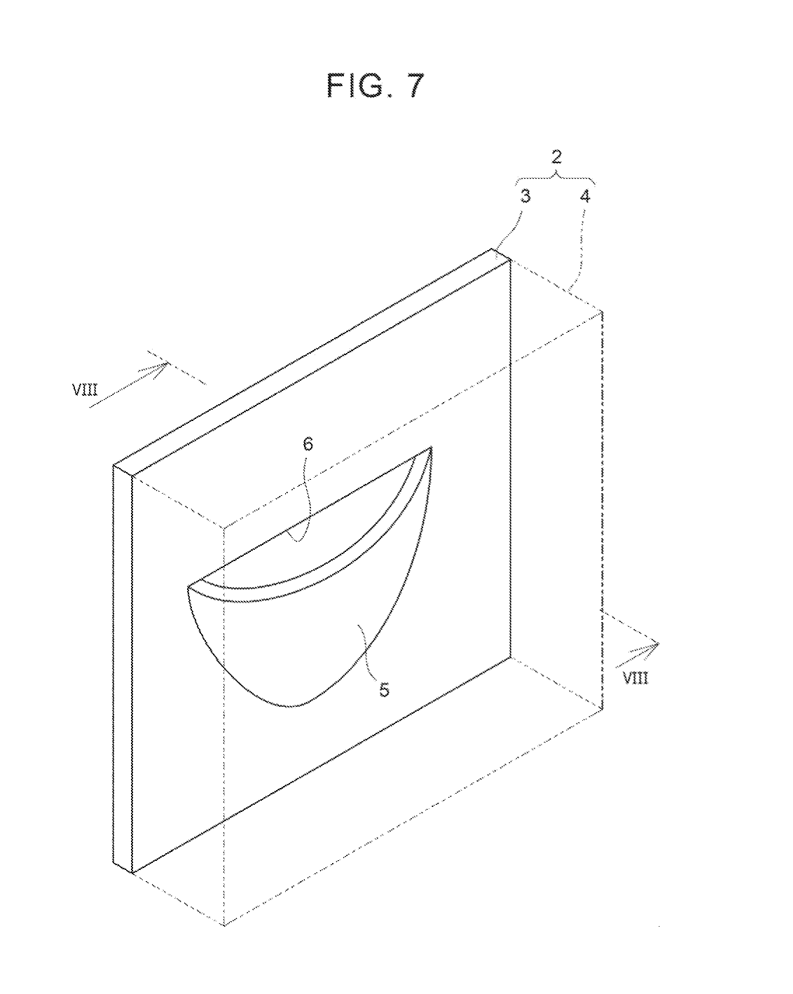

Next, a third embodiment of the invention will be described with reference to FIGS. 7 to 9. Hereafter, features different from those of the first embodiment will be described and descriptions on the same features as those of the first embodiment will be omitted.

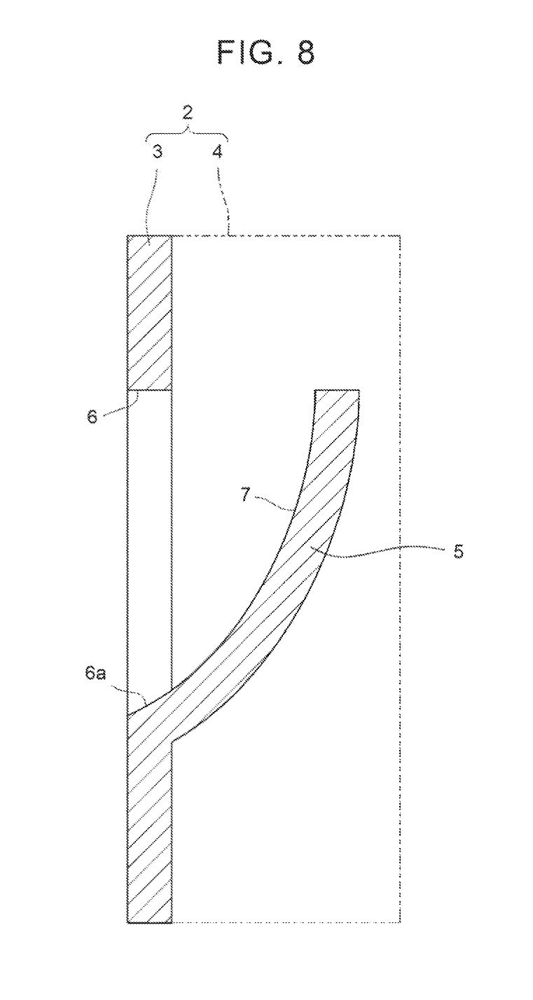

In the third embodiment, each projection portion 5 is a curved portion. In details, the projection portion 5 has a bag-shape and has an upward opening. That is, as shown in FIG. 8, the projection portion 5 extends obliquely upward from a lower end 6a of a hole 6. The projection portion 5 has a supporting side 7 facing the hole 6. That is, the supporting side 7 is oriented toward the metal plate 3 side.

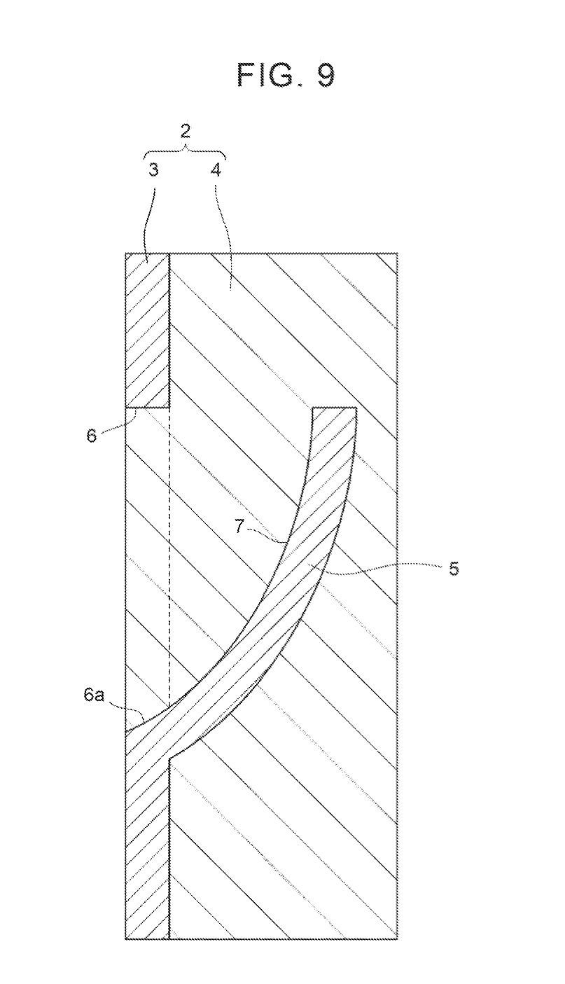

Next, with reference to FIG. 9, the insert molding through which the metal plate 3 and the insulating resin 4 are combined with each other will be described. First, the metal plate 3 is set in a molding die and the molding die is clamped. Then, molten resin is injected into a cavity of the molding die. As shown in FIG. 9, the insulating resin 4 accumulates on the metal plate 3 and some molten resin is introduced into a space defined by the projection portion 5 and communicated with the hole 6. The molten resin introduced into the spaces defined by the projection portions 5 and communicated with the holes 6 is cured. Therefore, the metal plate 3 and the insulating resin 4 are firmly combined with each other. At the same time, the holes 6 are filled with the molten resin.

As shown in FIG. 9, the projection portions 5 are entirely embedded in the insulating resin 4. That is, the projection portions 5 are not exposed on the surface of the insulating resin 4. Accordingly, insulating quality of the insulating resin 4 is surely maintained.

In the third embodiment, the projection portion 5 extends upward from the lower end 6a of the hole 6. Accordingly, an electromagnetic wave generated by an electric component placed near the bottom of the electromagnetic shield housing 1 can be effectively blocked.

What is claimed is:

1. An electromagnetic shield body including a metal plate and insulating resin combined with each other by insert molding, wherein:
the metal plate is provided with a projection portion projecting into the insulating resin from the metal plate; and
the projection portion has a supporting side that dams up and holds the insulating resin introduced into a space defined by the projection portion.

2. The electromagnetic shield body according to claim 1, wherein the projection portion is formed by subjecting a part of the metal plate to lancing and the projection portion covers a hole left in the metal plate through the lancing.

3. The electromagnetic shield body according to claim 2, wherein the projection portion has a beam-shape and is supported at one end by the metal plate.

4. The electromagnetic shield body according to claim 2, wherein the projection portion has a beam-shape and is supported at both ends by the metal plate.

5. The electromagnetic shield body according to claim 2, wherein the projection portion is a curved portion.

6. The electromagnetic shield body according to claim 1, wherein the projection portion is entirely embedded in the insulating resin.

7. A box provided with side-walls including the electromagnetic shield body according to claim 2, wherein the insulating resin of the electromagnetic shield body is disposed on an inner side of the metal plate in the box, and the projection portion extends upward from a lower end of the hole.

8. A box provided with side-walls including the electromagnetic shield body according to claim 2, wherein the insulating resin of the electromagnetic shield body is disposed on an inner side of the metal plate in the box.
